(19) United States
(12) Patent Application Publication
(10) Pub. No.: US 2026/0150734 A1
(43) Pub. Date: May 28, 2026

(54) SEMICONDUCTOR PACKAGE

(71) Applicant: SAMSUNG ELECTRONICS CO., LTD., Suwon-si (KR)

(72) Inventor: Raehyung DO, Suwon-si (KR)

(73) Assignee: SAMSUNG ELECTRONICS CO., LTD., Suwon-si (KR)

(21) Appl. No.: 19/389,334

(22) Filed: Nov. 14, 2025

(30) Foreign Application Priority Data
Nov. 27, 2024 (KR) 10-2024-0172448

(51) Int. Cl. H10W 70/65; H10W 42/00; H10W 74/10; H10W 90/00; H10W 72/00

(52) U.S. Cl. CPC H10W 70/65; H10W 42/121; H10W 74/117; H10W 90/701; H10W 72/884; H10W 90/734; H10W 90/754

(57) ABSTRACT

A semiconductor package may include: a package substrate including a plurality of bond fingers and a plurality of expansion pads respectively on the plurality of bond fingers; at least one semiconductor chip on an upper surface of the package substrate and including a plurality of chip pads; and bonding wires electrically connecting the plurality of chip pads and the plurality of expansion pads. Each of the bond fingers may have a first width, and each of the expansion pads may have a second width larger than the first width. End portions of the bonding wires may be bonded to upper surfaces of the expansion pads.

### CROSS-REFERENCE TO RELATED APPLICATION

This application claims priority under 35 U.S.C. § 119 to Korean Patent Application No. 10-2024-0172448, filed on November 27, 2024 in the Korean Intellectual Property Office, the disclosure of which is incorporated by reference herein in its entirety.

### BACKGROUND

### 1. Field

The disclosure relates to a package substrate, a semiconductor package and a method of manufacturing the semiconductor package, and more particularly, to a semiconductor package including bonding fingers to which bonding wires are connected and a method of manufacturing the same.

### 2. Description of Related Art

In manufacturing a semiconductor package, a semiconductor chip may be placed on a package substrate, and bonding wires may be used to connect chip pads of the semiconductor chip and bond fingers of the package substrate. Pitches between the bond fingers are gradually becoming finer, and there is a problem in that a defect occurs in a wire bonding process because a sufficient bonding area with the wire is not secured on a surface of the bond finger.

### SUMMARY

One or more embodiments provide a semiconductor package having bond fingers that may improve bonding quality with bonding wires.

According to an aspect of the disclosure, a semiconductor package may include: a package substrate including a plurality of bond fingers and a plurality of expansion pads respectively on the plurality of bond fingers; at least one semiconductor chip on an upper surface of the package substrate and including a plurality of chip pads; and bonding wires electrically connecting the plurality of chip pads and the plurality of expansion pads. Each of the bond fingers may have a first width, and each of the expansion pads may have a second width larger than the first width. End portions of the bonding wires may be bonded to upper surfaces of the expansion pads.

According to an aspect of the disclosure, a semiconductor package may include: at least one insulating layer; upper circuit wirings including a plurality of pad patterns on the at least one insulating layer; an upper protective layer on the at least one insulating layer and including a recess that exposes the plurality of pad patterns; a plurality of plating patterns respectively on the plurality of pad patterns exposed within the recess; expansion pads respectively on the plurality of plating patterns; at least one semiconductor chip on the upper protective layer and including a plurality of chip pads; and a plurality of bonding wires electrically connecting the plurality of chip pads and the expansion pads. Each of the plating patterns may have a first width, and each of the expansion pads may have a second width greater than the first width. End portions of the bonding wires may be bonded to upper surfaces of the expansion pads.

According to an aspect of the disclosure, a semiconductor package may include: a package substrate including a plurality of bond fingers and a plurality of expansion pads respectively on the plurality of bond fingers; at least one semiconductor chip on an upper surface of the package substrate and including a plurality of chip pads; and bonding wires electrically connecting the plurality of chip pads and the expansion pads. Each of the bond fingers may have a first width, and each of the expansion pads may have a second width larger than the first width. End portions of the bonding wires may be bonded to upper surfaces of the expansion pads, and the expansion pads and the bonding wires may include a same first material.

According to an aspect of the disclosure, a method of manufacturing a semiconductor package may include: providing a package substrate including a plurality of expansion pads; providing a semiconductor chip comprising a plurality of chip pads; placing the semiconductor chip on the package substrate; performing a wire bonding process to connect the chip pads to the expansion pads by: forming a free air ball (FAB) at one end portion of a wire drawn from a capillary and bonded to the chip pad; moving the capillary in a vertical direction to draw out the wire; moving the wire to the expansion pad with the capillary; and cutting a portion of the wire.

The method may further include: forming the expansion pad on a plating pattern of the package substrate by reciprocating and scrubbing a lower surface of a capillary on a free air ball (FAB).

The semiconductor chip may be placed on the package substrate such that a second surface, opposite a first surface comprising the expansion pads, faces the package substrate.

The cutting the portion of the wire may include: forming a free air ball (FAB) at a cut portion of the wire through electronic flame off (EFO), and moving the wire to another chip pad to continue performing the wire bonding process.

According to one or more embodiments, a semiconductor package may include a package substrate having a plurality of bond fingers and expansion pads respectively provided on the plurality of bond fingers, a semiconductor chip on the package substrate and having a plurality of chip pads, and bonding wires electrically connecting the plurality of chip pads and the expansion pads.

Each of the bond fingers may have a first diameter, and each of the expansion pads may have a second diameter greater than the first diameter. The expansion pads and the bonding wires may include the same material (e.g., gold). Accordingly, one end portion of the bonding wire may be sufficiently and securely bonded to an expanded pad area of the expansion pad, thereby improving the wire bonding quality.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a plan view illustrating a semiconductor package in accordance with one or more embodiments;

FIG. 2 is a cross-sectional view taken along the line A1-A1’ in FIG. 1 according to one or more embodiments;

FIG. 3 is a cross-sectional view taken along the line B1-B1’ in FIG. 1 according to one or more embodiments

FIG. 4 is an enlarged plan view illustrating portion ‘C1’ in FIG. 1 according to one or more embodiments

FIG. 5 is a cross-sectional view illustrating expansion pads according to one or more embodiments;

FIG. 6 is a view illustrating a method of manufacturing a semiconductor package in accordance with one or more embodiments

FIG. 7 is a view illustrating a method of manufacturing a semiconductor package in accordance with one or more embodiments;

FIG. 8 is a view illustrating a method of manufacturing a semiconductor package in accordance with one or more embodiments;

FIG. 9 is a view illustrating a method of manufacturing a semiconductor package in accordance with one or more embodiments;

FIG. 10 is a view illustrating a method of manufacturing a semiconductor package in accordance with one or more embodiments;

FIG. 11 is a view illustrating a method of manufacturing a semiconductor package in accordance with one or more embodiments;

FIG. 12 is a view illustrating a method of manufacturing a semiconductor package in accordance with one or more embodiments;

FIG. 13 is a view illustrating a method of manufacturing a semiconductor package in accordance with one or more embodiments;

FIG. 14 is a view illustrating a method of manufacturing a semiconductor package in accordance with one or more embodiments;

FIG. 15 is a view illustrating a method of manufacturing a semiconductor package in accordance with one or more embodiments;

FIG. 16 is a view illustrating a method of manufacturing a semiconductor package in accordance with one or more embodiments;

FIG. 17 is a view illustrating a method of manufacturing a semiconductor package in accordance with one or more embodiments;

FIG. 18 is a view illustrating a method of manufacturing a semiconductor package in accordance with one or more embodiments;

FIG. 19 is a view illustrating a method of manufacturing a semiconductor package in accordance with one or more embodiments;

FIG. 20 is a view illustrating a method of manufacturing a semiconductor package in accordance with one or more embodiments; and

FIG. 21 is a view illustrating a method of manufacturing a semiconductor package in accordance with one or more embodiments.

### DETAILED DESCRIPTION

Hereinafter, one or more embodiments will be explained in detail with reference to the accompanying drawings.

In the specification, spatially relative terms such as “top”, “bottom”, “upper”, “lower”, “up”, “down”, “horizontal,” “vertical” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

Further, skilled artisans will appreciate that elements in the drawings are illustrated for simplicity and may not have been necessarily drawn to scale. For example, the flow charts illustrate the method in terms of the most prominent steps involved to help to improve understanding of aspects of the present disclosure. Furthermore, in terms of the construction of the device, one or more components of the device may have been represented in the drawings by conventional symbols, and the drawings may show only those specific details that are pertinent to understanding the embodiments of the present disclosure so as not to obscure the drawings with details that will be readily apparent to those of ordinary skill in the art having benefit of the description herein.

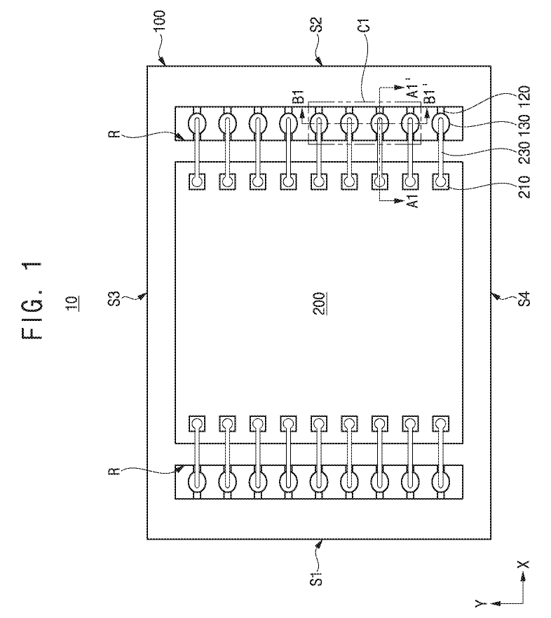

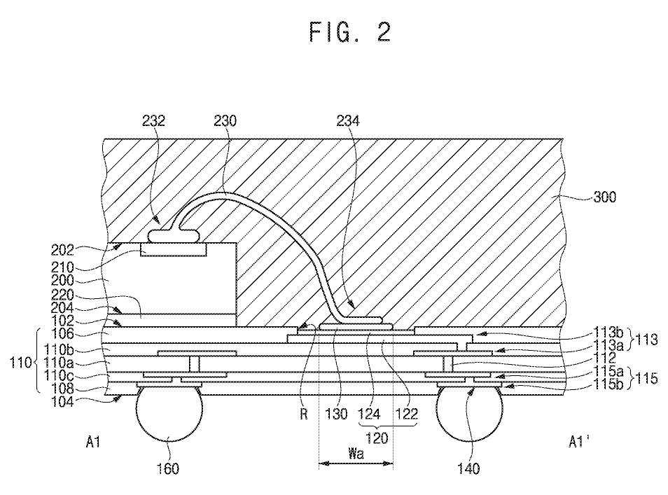

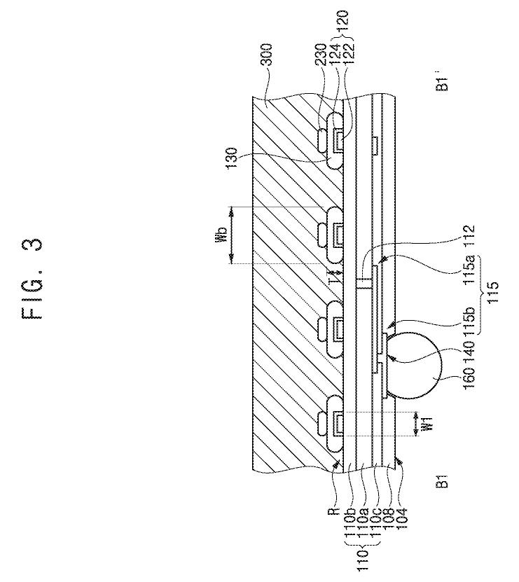

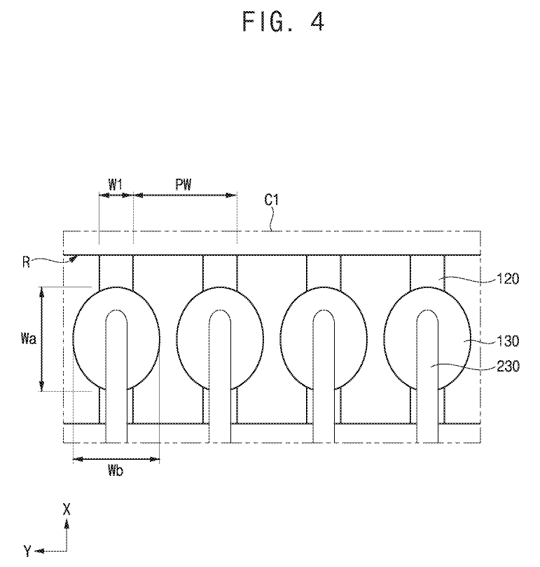

FIG. 1 is a plan view illustrating a semiconductor package in accordance with one or more embodiments. FIG. 2 is a cross-sectional view taken along the line A1-A1’ in FIG. 1. FIG. 3 is a cross-sectional view taken along the line B1-B1’ in FIG. 1. FIG. 4 is an enlarged plan view illustrating portion ‘C1’ in FIG. 1. FIG. 1 is a plan view illustrating the semiconductor package, wherein a molding member in FIG. 2 is omitted.

Referring to FIGS. 1 to 4, a semiconductor package 10 may include a package substrate 100, at least one semiconductor chip 200 and a plurality of bonding wires 230. In addition, the semiconductor package 10 may further include a molding member 300 and external connection members 160.

In one or more embodiments, the package substrate 100 may be a substrate having an upper surface 102 and a lower surface 104 opposite to the upper surface 102. For example, the package substrate 100 may include a printed circuit board PCB, a flexible substrate, a tape substrate, etc. The PCB may be a multilayer circuit board having vias and various circuits therein.

The package substrate 100 may include a first side portion S1 and a second side portion S2 extending in a direction parallel to a second direction (Y direction) and facing each other, and a third side portion S3 and a fourth side portion S4 extending in a direction parallel to a first direction (X direction) perpendicular to the second direction and facing each other.

The package substrate 100 may have a chip mounting region in a central region thereof. The chip mounting region may be a region where the semiconductor chip 200 is mounted. The package substrate 100 may include a plurality of bond fingers 120 that are arranged adjacent to the chip mounting region. The bond fingers 120 may be connected to wirings of the package substrate 100. The wirings may extend from an upper surface 102 or within the package substrate 100.

Although only a few bonding fingers are illustrated in the figures, it will be understood that the number, shape and arrangement of the bonding fingers are provided by way of example and that the present inventive concept is not limited thereto.

As illustrated in FIG. 2, the package substrate 100 may include a plurality of insulating layers 110a, 110b, 110c and wirings 113, 115 provided in the insulating layers respectively.

In particular, the package substrate 100 may include a core layer 110a, an upper insulating layer 110b on an upper surface of the core layer 110a, and a lower insulating layer 110c on a lower surface of the core layer 110a. The package substrate 100 may include a plurality of through vias 112 penetrating the core layer 110a, first upper circuit wirings 113a on the upper surface of the core layer 110a, second upper circuit wirings 113b provided in the upper insulating layer 110b, first lower circuit wirings 115a on the lower surface of the core layer 110a, and second lower circuit wirings 115b provided in the lower insulating layer 110c.

In one or more embodiments, the second upper circuit wirings 113b may extend on the uppermost insulating layer, that is, the upper insulating layer 110b among the plurality of insulating layers 110a, 110b, 110c. The second upper circuit wirings 113b may have signal wirings for electrical connection with the semiconductor chip. One end portions of the signal wirings may have pad patterns 122 for electrical connection with the semiconductor chip. A plurality of pad patterns 122 may be provided as portions (finger bodies) of the bond fingers. The second upper circuit wirings 113b may extend on the upper insulating layer 110b (uppermost insulating layer) and may include a trace including the pad pattern and an via pattern that is electrically connected to the first upper circuit wirings 113a through an opening formed in the upper insulating layer 110b.

In one or more embodiments, the package substrate 100 may include an upper protective layer 116 having a recess R that exposes the plurality of pad patterns 122. The upper protective layer 116 may cover the entire upper surface of the upper insulating layer 110b except for the pad patterns 122. An upper surface of the upper protective layer 116 may be provided as the upper surface 102 of the package substrate 100.

For example, two recesses R may extend in the second direction (Y direction) along the first side portion S1 and the second side portion S2 of the package substrate 100, respectively. The recesses R may have a rectangular shape. The plurality of pad patterns 122 may be spaced apart from each other in the second direction (Y direction) within each of the recesses R. Each of the pad patterns 122 may extend within the recess R in the first direction (X direction). The pad patterns 122 may be exposed from a bottom surface of the recess R.

In addition, the package substrate 100 may include a lower protective layer 118 covering the second lower circuit wirings 115b on a lower surface of the lower insulating layer 110c. A lower surface of the lower protective layer 118 may be provided as the lower surface 104 of the package substrate 100. At least a portion of the second lower circuit wirings 115b exposed by the lower protective layer 118 may be provided as a lower substrate pad 140.

In one or more embodiments, plating patterns 124 may be formed on the plurality of pad patterns 122 exposed within the recess R of the upper protective layer 116, respectively. The plating patterns 124 may cover surfaces of the pad patterns 122 and may be provided as portions (bond pad portions) of the bond fingers.

The plating pattern 124 may have a multilayer structure. For example, the plating pattern 124 may include a first plating pattern formed on the pad pattern 122 and a second plating pattern formed on the first plating pattern. The first plating pattern may include nickel (Ni), and the second plating pattern may include gold (Au). The first plating pattern may have a thickness within a range of 4 μm to 8 μm, and the second plating pattern may have a thickness within a range of 0.1 μm to 1.5 μm. Accordingly, the package substrate 100 may include the bond finger 120 having the pad pattern 122 as the finger body exposed within the recess R and the plating pattern 124 as the bond pad portion formed on the pad pattern 122.

In one or more embodiments, the package substrate 100 may include expansion pads 130 that respectively provided on the plating patterns 124. The expansion pad 130 may be formed by physically bonding one end portion of a wire drawn from a capillary CP to a surface of the plating pattern 124 using heat and ultrasonic waves. The expansion pad 130 may be physically bonded to the surface of the plating pattern 124. A flat upper surface of the expansion pad 130 may provide a plane on which the bonding wire 230 is bonded, so that the expansion pad 130 may serve as a landing pad for the bonding wire.

The expansion pad 130 may include a conductive material such as the bonding wire 230. For example, the conductive material may include gold (Au), silver (Ag), copper (Cu), aluminum (Al), etc. The second plating pattern of the plating pattern 124 may include gold (Au), and the expansion pad 130 formed on the second plating pattern may include gold (Au). Accordingly, the plating pattern 124 and the expansion pad 130 may be Au-Au bonded to each other.

As illustrated in FIG. 4, each of the bond fingers 120 may extend within the recess R in the first direction (X direction). The bond fingers 120 may be exposed from the bottom surface of the recess R. A thickness of the bond finger 120 may be within a range of 5 μm to 30 μm. A length in the first direction (X direction) of the bond finger 120, i.e., the plating pattern 124 may be within a range of 30 µm to 40 µm. A width W1 in the second direction (Y direction) of the bond finger 120, i.e., the plating pattern 124 may be within a range of 15 µm to 23 µm. A pitch PW between the bond fingers 120 may be within a range of 50 µm to 80 µm.

Each of the expansion pads 130 may have a width that is greater than a width of the plating pattern 124. The diameter of the expansion pad 130, i.e., a width in the second direction (Y direction), may be greater than the diameter of the plating pattern 124, i.e., the width W1 in the second direction (Y direction). The diameter of the expansion pad 130 may be within a range of 30 μm to 50 μm. A length in the first direction (X direction) of the expansion pad 130 may be less than a length in the first direction (X direction) of the plating pattern 124. The expansion pad 130 may cover a portion of the surface of the plating pattern 124. The expansion pad 130 may cover the plating pattern 124 and may contact the bottom surface of the recess R. A thickness of the expansion pad 130 may be within a range of 4 μm to 5 μm. A height T from the bottom surface of the recess R of the expansion pad 130 may be greater than a height of the plating pattern 124.

Each of the expansion pads 130 may have an oval shape when viewed in plan view. The length in the first direction (X direction) of the expansion pad 130, i.e., a major axis length Wa may be within a range of 35 μm to 50 μm. A width Wb (minor axis length) in the second direction (Y direction) of the expansion pad 130 may be within a range of 30 μm to 40 μm.

In one or more embodiments, the semiconductor chip 200 may be mounted on the chip mounting region of the package substrate 100. The semiconductor chip 200 may be mounted on the package substrate 100 by a wire bonding method. The semiconductor chip 200 may be placed such that a surface 204 opposite to a front surface 202 on which chip pads 210 are formed, i.e., an active surface, faces the package substrate 100. The semiconductor chip 200 may have a rectangular shape with four sides when viewed in plan view. The chip pads 210 may be arranged on the front surface 202 of the semiconductor chip 200 to be spaced apart from each other along first and second sides facing each other.

The semiconductor chip 200 may be attached to the package substrate 100 by an adhesive film 220. The chip pads 210 of the semiconductor chip 200 may be electrically connected to the expansion pads 130 of the package substrate 100 by the bonding wires 230 as conductive connection members. One end portion 232 of the bonding wire 230 may be bonded to the chip pad 210, and the other end portion 234 of the bonding wire 230 may be bonded to an upper surface of the corresponding expansion pad 130. For example, a thickness of the semiconductor chip 200 may be within a range of 40 μm to 120 μm. A thickness of the adhesive film 220 may be within a range of 5 μm to 30 μm.

As illustrated in FIGS. 3 and 4, each of the bond fingers 120 has a relatively narrow width W1, but each of the expansion pads 130 formed on the bond fingers 120 may have a relatively wide width Wb. Accordingly, the other end portion 234 of the bonding wire 230 may be sufficiently and securely bonded to the expanded pad area of the expansion pad 130, thereby improving the wire bonding quality.

In one or more embodiments, the molding member 300 may be provided on the upper surface 102 of the package substrate 100 to cover the semiconductor chip 200 and the bonding wires 230. The molding member may include a thermosetting resin, for example, an epoxy mold compound (EMC).

In one or more embodiments, the lower substrate pads 140 for providing an electric signal may be formed on the lower surface 104 of the package substrate 100. The lower substrate pads 140 may be exposed by the lower protective layer 118. The external connection member 160 may be disposed on the lower substrate pad 140 of the package substrate 100 for electrical connection with an external device. For example, the external connection member 160 may be a solder ball. The semiconductor package 10 may be mounted on a module substrate via the solder balls to constitute a memory module.

As mentioned above, the semiconductor package 10 may include the package substrate 100 having the plurality of bond fingers 120 and the expansion pads 130 respectively provided on the plurality of bond fingers 120, the semiconductor chip 200 on the upper surface of the package substrate 100 and having the plurality of chip pads 210, and the bonding wires 230 electrically connecting the plurality of chip pads 210 and the expansion pads 130. Each of the bond fingers 120 may include the pad pattern 122 extending within the recess R and the plating pattern 124 covering the surface of the pad pattern 122.

Each of the bond fingers 120 may have a first diameter W1, and each of the expansion pads 130 may have a second diameter Wb greater than the first diameter W1. The expansion pads 130 and the bonding wires 230 may include the same material (e.g., gold). Accordingly, the other end portion 234 of the bonding wire 230 may be sufficiently and securely bonded to the expanded pad area of the expansion pad 130, thereby improving the wire bonding quality.

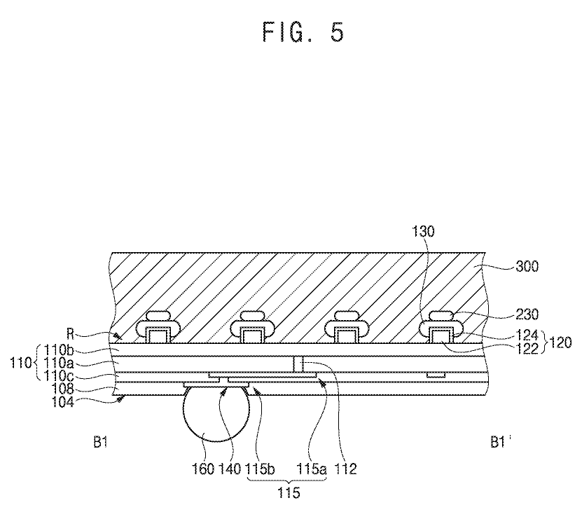

FIG. 5 is a cross-sectional view illustrating expansion pads according to another embodiment. FIG. 5 is a cross-sectional view taken along the line B1-B1’ in FIG. 1.

Referring to FIG. 5, an expansion pad 130 may cover an upper portion of a bond finger 120. A lower side wall of the bond finger 120 may be exposed by the expansion pad 130. The expansion pad 130 may be spaced apart from a bottom surface of a recess R. A thickness of the bond finger 120 may be greater than a thickness of the expansion pad 130. A height of the expansion pad 130 from the bottom surface of the recess R may be greater than a height of a plating pattern 124.

Hereinafter, a method of manufacturing the semiconductor package of FIG. 1 will be described.

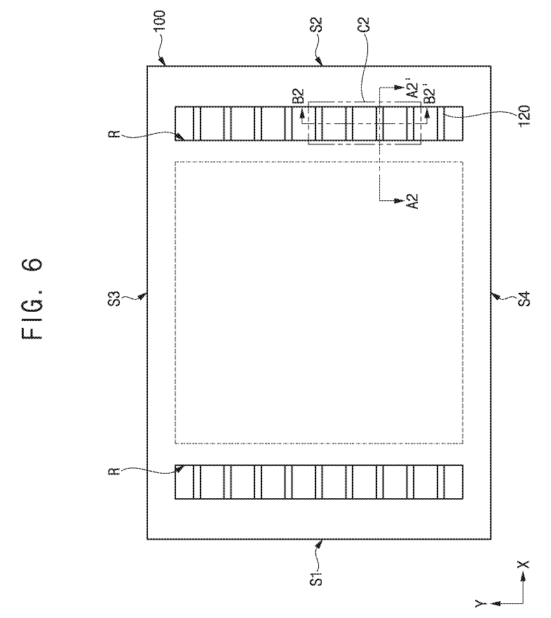

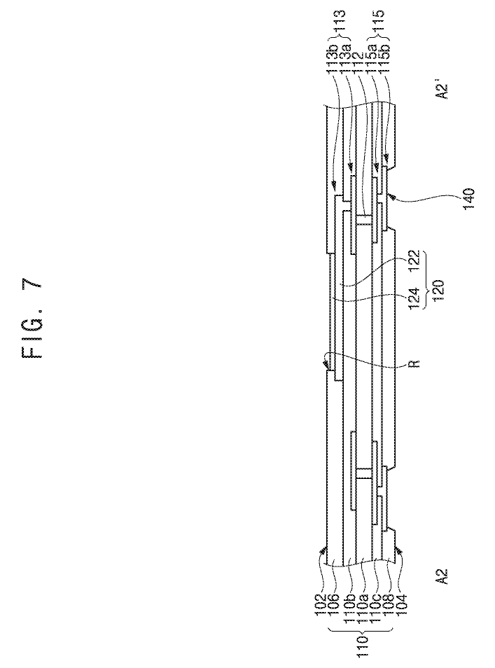

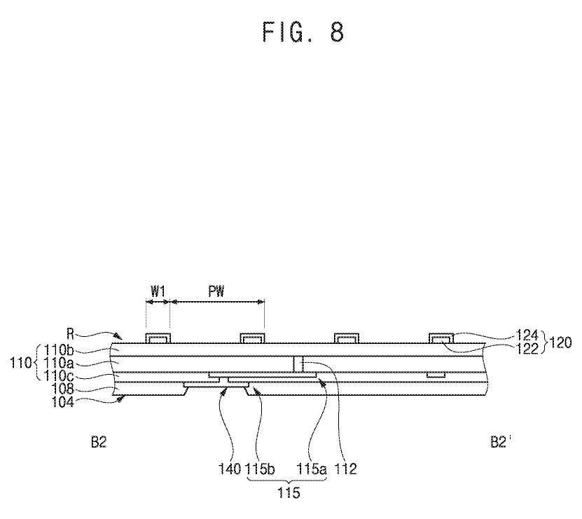

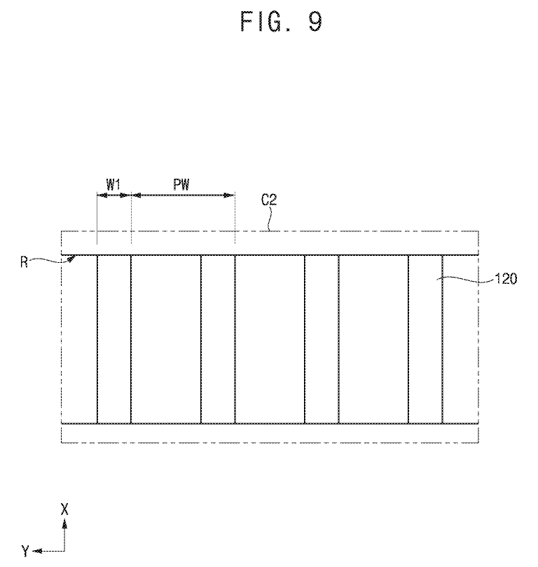

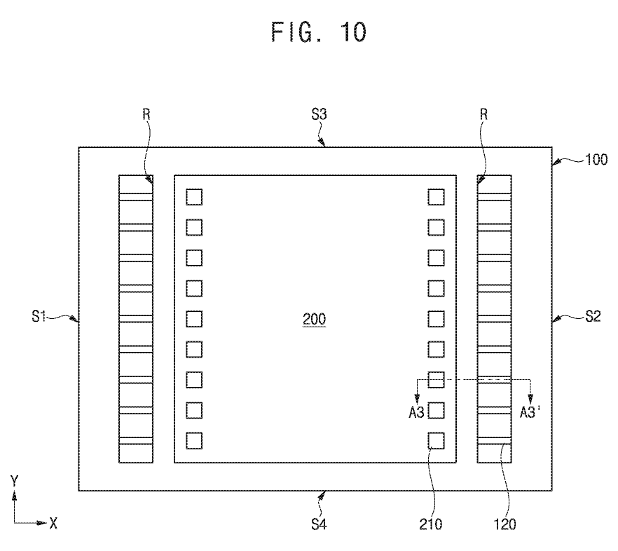

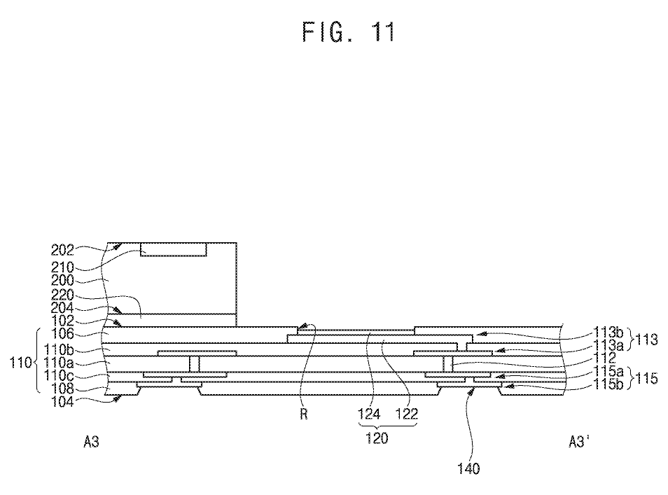

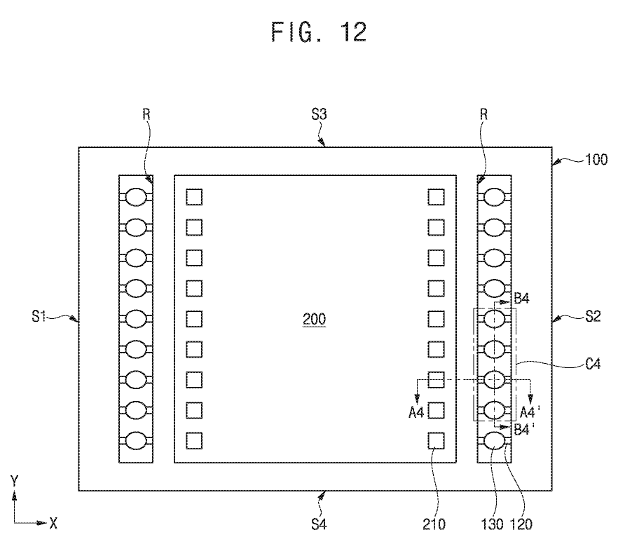

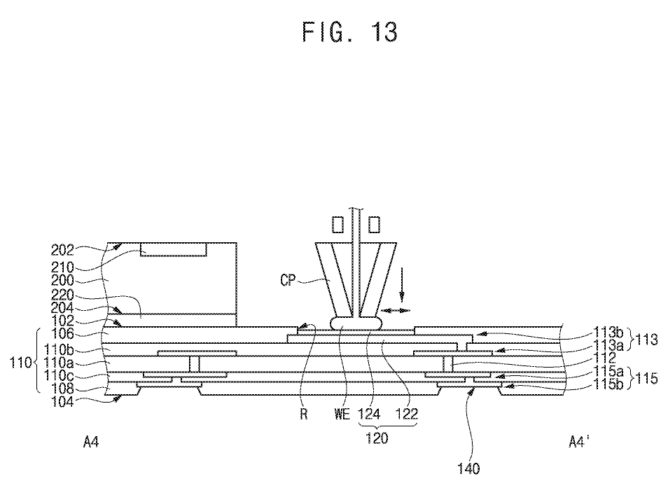

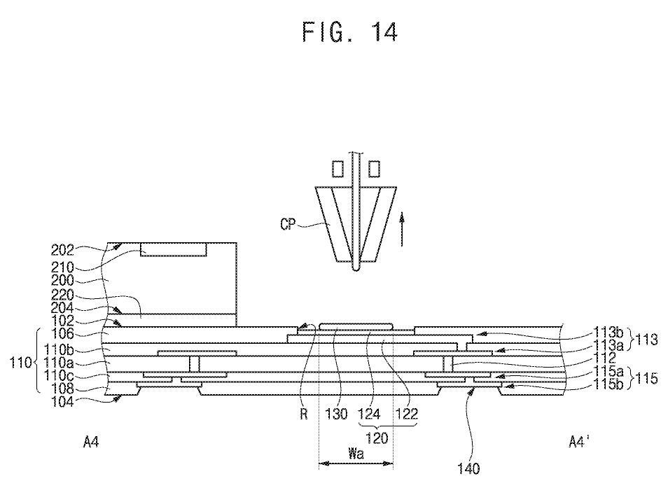

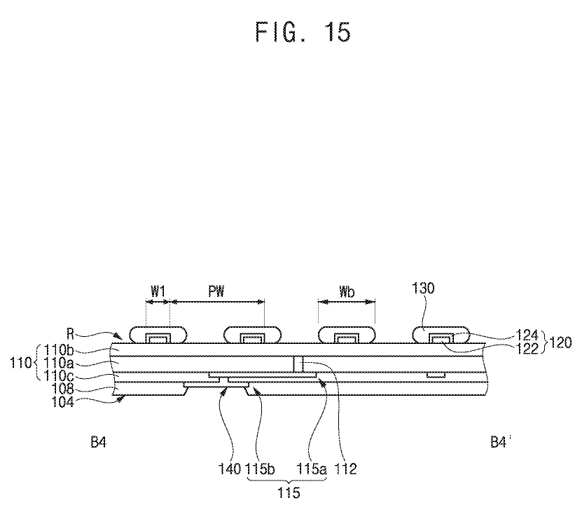

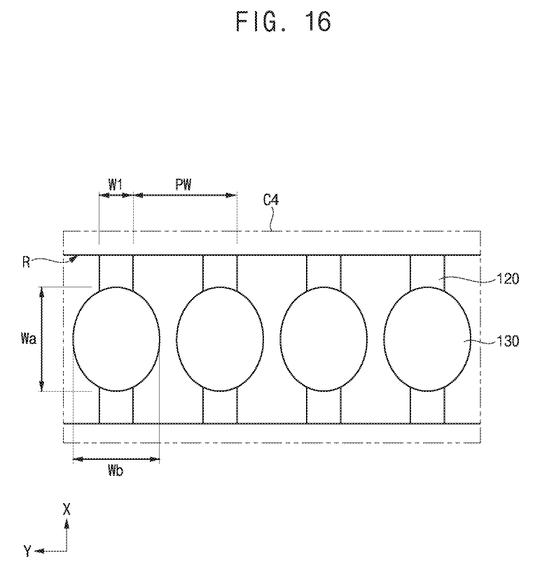

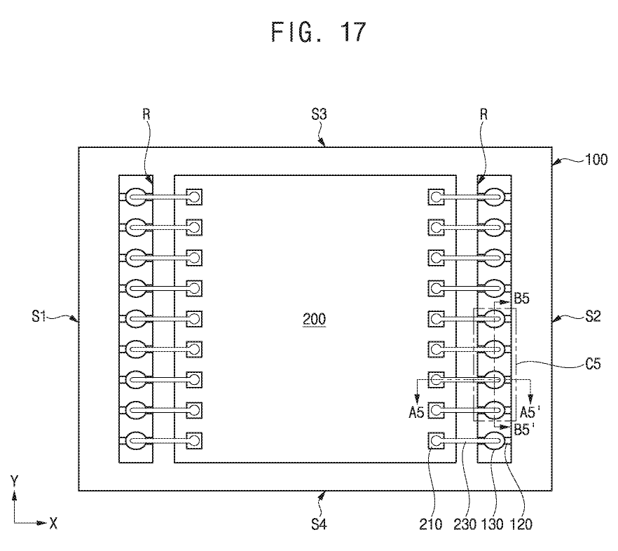

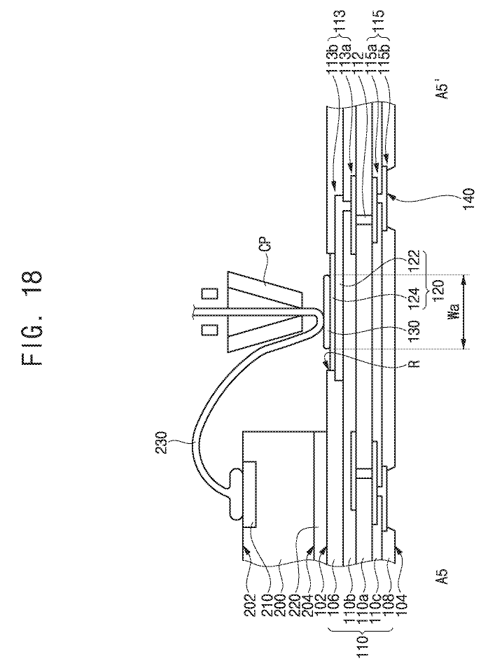

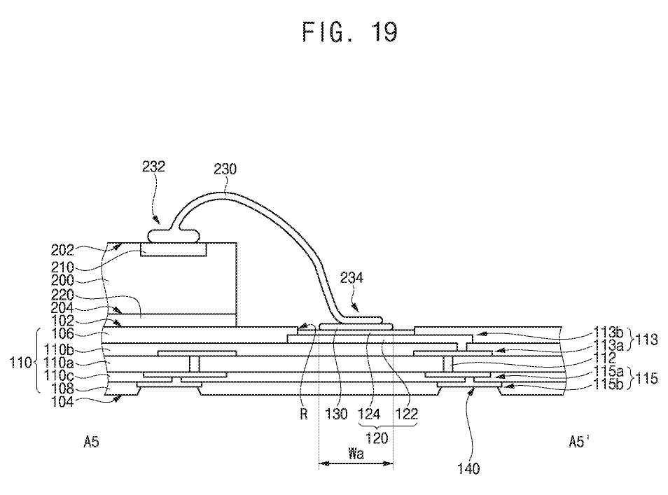

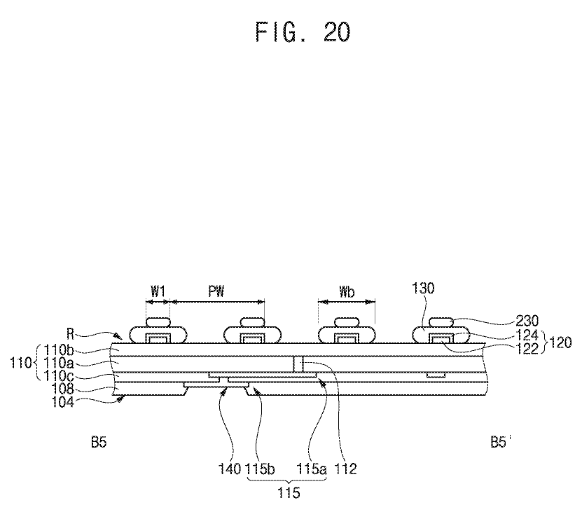

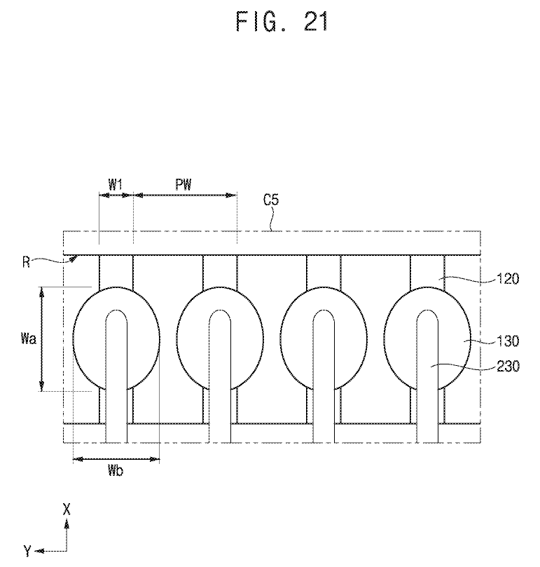

FIGS. 6 to 21 are views illustrating a method for manufacturing a semiconductor package in accordance with one or more embodiments. FIGS. 6, 10, 12 and 17 are plan views illustrating a method of manufacturing a semiconductor package in accordance with one or more embodiments. FIG. 7 is a cross-sectional view taken along the line A2-A2’ in FIG. 6. FIG. 8 is a cross-sectional view taken along the line B2-B2’ in FIG. 6. FIG. 9 is an enlarged plan view illustrating portion ‘C2’ in FIG. 6. FIG. 11 is a cross-sectional view taken along the line A3-A3’ in FIG. 10. FIGS. 13 and 14 are cross-sectional views taken along the line A4-A4’ in FIG. 12. FIG. 15 is a cross-sectional view taken along the line B4-B4’ in FIG. 12. FIG. 16 is an enlarged plan view illustrating portion ‘C4’ in FIG. 6. FIGS. 18 and 19 are cross-sectional views taken along the line A5-A5’ in FIG. 17. FIG. 20 is a cross-sectional view taken along the line B5-B5’ in FIG. 17. FIG. 21 is an enlarged plan view illustrating portion ‘C5’ in FIG. 17.

Referring to FIGS. 6 to 9, a package substrate 100 having a plurality of bond fingers 120 may be provided.

In one or more embodiments, the package substrate 100 may be a multilayer circuit board having an upper surface 102 and a lower surface 104 opposite to the upper surface 102. For example, the package substrate 100 may be a printed circuit board PCB including wirings provided in each of a plurality of layers and vias for connecting them.

As illustrated in FIG. 6, the package substrate 110 may include a first side portion S1 and a second side portion S2 extending in a direction parallel to a second direction (Y direction) and facing each other, and a third side portion S3 and a fourth side portion S4 extending in a direction parallel to a first direction (X direction) perpendicular to the second direction and facing each other. The package substrate 100 may have a chip mounting region in a central region thereof. The chip mounting region may be a region where a semiconductor chip is to be mounted. The chip mounting region may have a rectangular shape.

In particular, the package substrate 100 may include a core layer 110a, an upper insulating layer 110b on an upper surface of the core layer 110a, and a lower insulating layer 110c on a lower surface of the core layer 110a. The package substrate 100 may include a plurality of through vias 112 penetrating the core layer 110a, first upper circuit wirings 113a on the upper surface of the core layer 110a, second upper circuit wirings 113b provided in the upper insulating layer 110b, first lower circuit wirings 115a on the lower surface of the core layer 110a, and second lower circuit wirings 115b provided in the lower insulating layer 110c.

For example, the insulating layer may include an insulating material such as a thermosetting resin such as epoxy resin or a thermoplastic resin such as polyimide. The insulating layer may include a resin impregnated in a core material such as organic fiber (glass fiber), for example, a prepreg, FR-4, BT (Bismaleimide Triazine), etc.

The second upper circuit wirings 113b may extend on the uppermost insulating layer, that is, the upper insulating layer 110b among the plurality of insulating layers 110a, 110b, 110c. The second upper circuit wirings 113b may have signal wirings for electrical connection with the semiconductor chip. One end portions of the signal wirings may have pad patterns 122 for electrical connection with the semiconductor chip.

Although only a few wirings and pad patterns are illustrated in the figures, it will be understood that the number, shape and arrangement of the wirings and pad patterns are provided by way of example and that the present disclosure is not limited thereto.

In one or more embodiments, the package substrate 100 may include an upper protective layer 116 covering the second upper circuit wirings 113b on an upper surface of the upper insulating layer 110b and a lower protective layer 118 covering the second lower circuit wirings 115b on a lower surface of the lower insulating layer 110c. An upper surface of the upper protective layer 116 may be provided as the upper surface 102 of the package substrate 100, and a lower surface of the lower protective layer 118 may be provided as the lower surface 104 of the package substrate 100.

The upper protective layer 116 may have a recess R that exposes the pad patterns 122 of the second upper circuit wirings 113b.

For example, a solder resist layer may be formed on the upper surface of the upper insulating layer 110b, and an exposure and development process may be performed to form the upper protective layer 116 having the recess R. The upper protective layer 116 may cover the entire upper surface of the upper insulating layer 110b except for the pad patterns 122.

For example, two recesses R may extend in the second direction (Y direction) along the first side portion S1 and the second side portion S2 of the package substrate 100, respectively. The recess R may have a rectangular shape. The plurality of pad patterns 122 may be spaced apart from each other along the second direction (Y direction) within the recess R. Each of the pad patterns 122 may extend within the recess R in the first direction (X direction). The pad patterns 122 may be exposed from a bottom surface of the recess R.

Accordingly, the second upper circuit wirings 113b may include the plurality of pad patterns 122 that are exposed from the recess R of the upper protective layer 116 and serve as portions (finger bodies) of the bond fingers.

In addition, the lower protective layer 118 may be formed on the lower surface of the lower insulating layer 110c to cover the second lower circuit wirings 115b. The lower surface of the lower protective layer 118 may be provided as the lower surface 104 of the package substrate 100. At least a portion of the second lower circuit wirings 115b exposed by the lower protective layer 118 may be provided as a lower substrate pad 140.

In one or more embodiments, plating patterns 124 may be formed on the plurality of pad patterns 122 exposed within the recess R of the upper protective layer 116, respectively. The plating patterns 124 may cover surfaces of the pad patterns 122 and may be provided as portions (bond pad portions) of the bond fingers.

For example, a plating process may be performed to form a first plating pattern on the pad pattern 122, and a second plating process may be performed to form a second plating pattern on the first plating pattern. The first plating pattern may include nickel (Ni), and the second plating pattern may include gold (Au). The first plating pattern may have a thickness within a range of 4 μm to 8 μm, and the second plating pattern may have a thickness within a range of 0.1 μm to 1.5 μm.

Accordingly, the bond finger 120 may include the pad pattern 122 as the finger body exposed within the recess R and the plating pattern 124 as the bond pad portion formed on the pad pattern 122.

As illustrated in FIG. 9, each of the bond fingers 120 may extend within the recess R in the first direction (X direction). The bond fingers 120 may be exposed from the bottom surface of the recess R. A thickness of the bond finger 120 may be within a range of 5 μm to 30 μm. A length in the first direction (X direction) of the bond finger 120, i.e., the plating pattern 124 may be within a range of 30 µm to 40 µm. A width W1 in the second direction (Y direction) of the bond finger 120, i.e., the plating pattern 124 may be within a range of 15 µm to 23 µm. A pitch PW between the bond fingers 120 may be within a range of 50 µm to 80 µm.

Referring to FIGS. 10 and 11, at least one semiconductor chip 200 may be mounted on the package substrate 100 by a wire bonding method.

In one or more embodiments, the at least one semiconductor chip 200 may be placed on the package substrate 100. The semiconductor chip 200 may be attached to the upper protective layer 116 of the package substrate 100 by an adhesive film 220. The semiconductor chip 200 may be arranged such that a surface 204 opposite to a front surface 202 on which chip pads 210 are formed, that is, an active surface, faces the package substrate 100. The semiconductor chip 200 may have a rectangular shape with four sides when viewed in plan view. The chip pads 210 may be arranged on the front surface 202 of the first semiconductor chip 200 to be spaced apart from each other along first and second sides facing each other. For example, a thickness of the semiconductor chip 200 may be within a range of 40 μm to 120 μm. A thickness of the adhesive film 220 may be within a range of 5 μm to 30 μm.

Referring to FIGS. 12 to 15, expansion pads 130 may be formed on the plating patterns 124, respectively.

As illustrated in FIGS. 13 and 14, a free air ball (FAB) may be formed on one end portion WE of a wire drawn from a capillary CP, and after the free air ball is brought into contact with an upper surface of the plating pattern 124, a portion of the wire may be cut. By reciprocating and scrubbing a lower surface of the capillary CP on the free air ball, the expansion pad 130 having a flat upper surface may be formed. The free air ball may be physically bonded to the surface of the plating pattern 124 using heat and ultrasonic waves. The flat upper surface of the expansion pad 130 may provide a plane on which a bonding wire is bonded in a following wire bonding process, so that the expansion pad 130 may be provided as a landing pad for the bonding wire.

The expansion pad 130 may include a conductive material such as the bonding wire 230. For example, the conductive material may include gold (Au), silver (Ag), copper (Cu), aluminum (Al), etc. The second plating pattern of the plating pattern 124 may include gold (Au), and the expansion pad 130 formed on the second plating pattern may include gold (Au). Accordingly, the plating pattern 124 and the expansion pad 130 may be Au-Au bonded to each other.

As illustrated in FIGS. 15 and 16, each of the expansion pads 130 may have an expanded width that is greater than a width of the free air ball. The diameter of the expansion pad 130, i.e., a width in the second direction (Y direction), may be greater than the diameter of the plating pattern 124, i.e., the width W1 in the second direction (Y direction). The diameter of the expansion pad 130 may be within a range of 30 μm to 50 μm.

A length in the first direction (X direction) of the expansion pad 130 may be less than a length in the first direction (X direction) of the plating pattern 124. The expansion pad 130 may cover a portion of the surface of the plating pattern 124. The expansion pad 130 may cover the plating pattern 124 and may contact the bottom surface of the recess R. A thickness of the expansion pad 130 may be within a range of 4 μm to 5 μm. A height T from the bottom surface of the recess R of the expansion pad 130 may be greater than a height of the plating pattern 124.

Each of the expansion pads 130 may have an oval shape when viewed in plan view. The length in the first direction (X direction) of the expansion pad 130, i.e., a major axis length Wa may be within a range of 35 μm to 50 μm. A width Wb in the second direction (Y direction) of the expansion pad 130 may be within a range of 30 μm to 40 μm.

Referring to FIGS. 17 to 21, a wire bonding process may be performed to connect the chip pads 210 of the semiconductor chip 200 to the expansion pads 130 of the package substrate 100. The chip pads 210 of the semiconductor chip 200 may be connected to the expansion pads 130 by bonding wires 230 as conductive connection members.

In particular, a free air ball (FAB) may be formed at one end portion 232 of a wire drawn from a capillary CP and bonded to the chip pad 210 of the semiconductor chip 200, and then the capillary CP may move in a vertical direction to draw out the wire. Then, the capillary CP may move the wire onto the expansion pad 130 in the recess R to contact a surface of the expansion pad 130, and then cut a portion of the wire. When cutting the portion of the wire, a free air ball (FAB) may be formed at the cut portion of the wire through electronic flame off (EFO), and then the wire may move onto another chip pad to continue performing the bonding wire process.

Each of the bond fingers 120 may have a relatively narrow diameter W1, and each of the expansion pads 130 formed on the bond finger 120 may have a relatively wide diameter Wb. Accordingly, the other end portion 234 of the bonding wire 230 may be sufficiently and securely bonded to the expanded pad area of the expansion pad 130, thereby improving the wire bonding quality.

Then, a molding member (300, see FIG. 2) may be formed on the upper surface 102 of the package substrate 100 to cover the semiconductor chip 200 and the bonding wires 230. The molding member may include a thermosetting resin, for example, an epoxy mold compound (EMC).

Then, external connection members (160, see FIG. 2) may be formed on the lower substrate pads 140 on the lower surface 104 of the package substrate 100 to complete the semiconductor package 10 of FIG. 1.

For example, the external connection members may include solder balls. The external connection members may be formed on the lower substrate pads 140 of the package substrate 100 by a solder ball attach process, respectively.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is Claimed is:

1. A semiconductor package comprising:
a package substrate comprising a plurality of bond fingers and a plurality of expansion pads respectively on the plurality of bond fingers;
at least one semiconductor chip on an upper surface of the package substrate and comprising a plurality of chip pads; and
bonding wires electrically connecting the plurality of chip pads and the plurality of expansion pads,
wherein each of the bond fingers has a first width, and each of the expansion pads has a second width larger than the first width, and
wherein end portions of the bonding wires are bonded to upper surfaces of the expansion pads.

2. The semiconductor package of claim 1, wherein each of the bond fingers comprises:
a pad pattern on the upper surface of the package substrate; and
a plating pattern on a surface of the pad pattern.

3. The semiconductor package of claim 1, wherein the first width is within a range of 15 μm to 23 μm.

4. The semiconductor package of claim 1, wherein the second width is within a range of 30 μm to 50 μm.

5. The semiconductor package of claim 1, wherein each of the expansion pads has an oval shape when viewed in plan view.

6. The semiconductor package of claim 5, wherein each of the expansion pads has a major axis length within a range of 35 μm to 50 μm and a minor axis length within a range of 30 μm to 40 μm.

7. The semiconductor package of claim 1, wherein the expansion pads and the bonding wires comprise a same first material.

8. The semiconductor package of claim 7, wherein the first material of the expansion pads and the bonding wires comprises at least one of gold (Au), silver (Ag), copper (Cu), and aluminum (Al).

9. The semiconductor package of claim 1, wherein the package substrate comprises an upper protective layer comprising the upper surface of the package substrate and a recess that exposes the plurality of bond fingers.

10. The semiconductor package of claim 1, wherein the at least one semiconductor chip comprises a first surface comprising the chip pads and a second surface opposite the first surface and facing the package substrate.

11. A semiconductor package comprising:
at least one insulating layer;
upper circuit wirings comprising a plurality of pad patterns on the at least one insulating layer;
an upper protective layer on the at least one insulating layer and comprising a recess that exposes the plurality of pad patterns;
a plurality of plating patterns respectively on the plurality of pad patterns exposed within the recess;
expansion pads respectively on the plurality of plating patterns;
at least one semiconductor chip on the upper protective layer and comprising a plurality of chip pads; and
a plurality of bonding wires electrically connecting the plurality of chip pads and the expansion pads,
wherein each of the plating patterns has a first width, and each of the expansion pads has a second width greater than the first width, and
wherein end portions of the bonding wires are bonded to upper surfaces of the expansion pads.

12. The semiconductor package claim 11, wherein the first width is within a range of 15 μm to 23 μm.

13. The semiconductor package of claim 11, wherein the second width is within a range of 30 μm to 50 μm.

14. The semiconductor package of claim 11, wherein each of the expansion pads has an oval shape when viewed in plan view.

15. The semiconductor package of claim 14, wherein each of the expansion pads has a major axis length within a range of 35 μm to 50 μm and a minor axis length within a range of 30 μm to 40 μm.

16. The semiconductor package of claim 11, wherein the expansion pads and the bonding wires comprise a same first material.

17. The semiconductor package of claim 16, wherein the first material of the expansion pads and the bonding wires comprises at least one of gold (Au), silver (Ag), copper (Cu), and aluminum (Al).

18. The semiconductor package of claim 11, wherein the pad pattern comprises copper (Cu).

19. The semiconductor package of claim 11, wherein the at least one semiconductor chip comprises a first surface comprising the chip pads and a second surface opposite the first surface and facing the upper protective layer.

20. A semiconductor package comprising:
a package substrate comprising a plurality of bond fingers and a plurality of expansion pads respectively on the plurality of bond fingers;
at least one semiconductor chip on an upper surface of the package substrate and comprising a plurality of chip pads; and
bonding wires electrically connecting the plurality of chip pads and the expansion pads,
wherein each of the bond fingers has a first width, and each of the expansion pads has a second width larger than the first width,
wherein end portions of the bonding wires are bonded to upper surfaces of the expansion pads, and
wherein the expansion pads and the bonding wires comprise a same first material.
